(19) United States
(12) Patent Application Publication
(10) Pub. No.: US 2006/0073628 A1
(43) Pub. Date: Apr. 6, 2006

(54) Solid-state imaging device and method of manufacturing the same

(75) Inventors: Satoshi Uchiya, Kawasaki (JP); Taro Moriya, Kawasaki (JP); Junichi Yamamoto, Kawasaki (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KAWASAKI (JP)

(21) Appl. No.: 11/240,602

(22) Filed: Oct. 3, 2005

(30) Foreign Application Priority Data
Oct. 6, 2004 (JP) 2004-293981

(51) Int. Cl. H01L 21/00

(52) U.S. Cl. 438/57

(57) ABSTRACT

The invention reduces dark current of a solid-state imaging device. A solid-state imaging device containing photodiode comprises: a diffusion layer placed side by side with the photodiode on the surface of an N-type semiconductor substrate; a first polycrystalline silicon electrode provided on the diffusion layer; a first Al interconnect provided on the first polycrystalline silicon electrode; a contact plug connecting the lower surface of the first Al interconnect and the first polycrystalline silicon electrode; and an adhesive film that is a titanium-containing film selectively provided within the contact plug.

This application is based on Japanese patent application NO. 2004-293981, the content of which is incorporated hereinto by reference.

### BACKGROUND OF THE INVENTION

1. Field of the Invention

This invention relates to a solid-state imaging device and a method of manufacturing the same.

2. Description of the Related Art

Conventionally, the solid-state imaging device of a CCD (charge coupled device) type or a CMOS type is a combination of photodiodes having a photoelectric conversion function and a transfer CCD transferring charges or a gate device formed on the surface of a semiconductor substrate with gate electrodes and a interconnect layer formed on these elements (Japanese Laid-open patent application No. 2003-229556). Japanese Laid-open patent application No. 2003-229556 discloses that metal Ti (titanium) or an alloy material containing Ti is used on and under the interconnect layer and in the vicinity of a plug layer of the solid-state imaging device.

For example, a CCD type solid-state imaging device is manufactured by the following procedure. First, a gate oxide film is formed on the semiconductor substrate in which a diffusion layer was formed, and a polycrystalline silicon electrode is selectively formed by the lithography and etching technology. Next, an interlayer film is formed and contact holes are selectively formed therein by the lithography and etching technology. Next, a Ti film and a TiN (titanium nitride) film are formed successively by sputtering. Subsequently, a tungsten layer is deposited by a CVD method, and subjected to etchback using SF6 gas, whereby only left it in the contact holes. Then, an Al (aluminum) film is formed by sputtering and selectively left by the lithography and etching technology.

Next, an interlayer film is formed and subjected to a sintering treatment with hydrogen gas. By the sintering treatment with hydrogen gas, hydrogen is doped into the semiconductor substrate to effect extinction of interface levels, which reduces dark current of the photodiodes and transfer CCD.

### SUMMARY OF THE INVENTION

However, when Ti metal or an alloy material containing Ti exists under the metal interconnect, these metal materials adsorb hydrogen, and hence it is difficult to reduce the dark current.

In order to solve this problem, Japanese Laid-open patent application No. 2003-229556 discloses a method where a material containing no titanium, for example, a nitride of silicon and an oxide of silicon, is used for antireflection coating, a barrier layer, and an adhesive film of the CMOS type image sensor. On the other hand, Japanese Laid-open patent application No. 1996-37236 discloses a technology of establishing contact between a metal interconnect layer and a substrate with a through electrode through a plug that has a tungsten silicide film as an underlayer and act as the adhesive film. However, with the technologies disclosed in the above-mentioned Japanese Laid-open patent application No. 2003-229556 and Japanese Laid-open patent application No. 1996-37236, contact resistance between the contact plug and an electroconductive region in contact with an bottom surface of the contact plug increases to cause interconnect delay.

According to the present invention, there is provided a solid-state imaging device including a photosensor, the solid-state imaging device comprising: a substrate, an electroconductive region provided on the substrate, an insulating film formed on the electroconductive region, metal interconnect provided on the insulating film, a contact plug that is provided in the insulating film and connects the lower surface of the metal interconnect and the electroconductive region, and a titanium-containing film selectively formed within the contact plug.

According to the present invention, since the titanium-containing film is selectively formed within the contact plug, adsorption of hydrogen under the metal interconnect can be suppressed, and consequently the dark current can be reduced. Moreover, since the titanium-containing film is formed within the contact plug, adherence between the contact plug and the electroconductive region can be improved. Therefore, the contact resistance between the contact plug and the electroconductive region can be reduced. Thus, the interconnect delay can be suppressed. In the present invention, the adhesive film may have a structure, for example, that covers the whole bottom and side surfaces of the contact plug. With this structure, the adherence between the contact plug and the electroconductive region can be improved more surely.

In the present invention, the titanium-containing film may be formed only in a lower part and on a side face of the contact plug. Moreover, the solid-state imaging device may have a structure where the insulating film and the metal interconnect are in direct contact with each other. With this structure, adsorption of hydrogen under the metal interconnect can be controlled even more surely.

In the present invention, the photosensor (photoelectric transducer) may be, for example, a photodiode. Here, the photosensors are regularly arranged, for example, in the form of a line or matrix on the semiconductor substrate. The photosensors receive illumination of light and convert the light into charges in proportion to the amount of incident light, generating the charges.

The electroconductive region in the present invention means a region having conductivity, which includes, for example, a diffusion layer and the like formed in the vicinity of a surface of the semiconductor substrate as well as a interconnect, a contact plug, an electrode, and the like. As an electric electroconductive material that constitutes the electroconductive region, there are exemplified metals, alloy metals, polycrystalline silicon doped with an impurity, and the like.

Note that, in the present invention, the titanium-containing film only needs to be formed within the contact plug in a region between a bottom surface of the metal interconnect and a top surface of the electroconductive region; for example, a titanium-containing film that acts as antireflection coating may be formed on the top surface of the metal interconnect.

Moreover, according to the present invention, there is provided a method of manufacturing a solid-sate imager, comprising: forming an insulating film on the semiconductor substrate in which a photosensor is provided; selectively removing the insulating film to form a contact hole; forming an adhesive film containing a titanium-containing film on the insulating film in which the contact hole was formed; forming a tungsten film on the adhesive film so that the tungsten film fills the contact hole; removing the tungsten film formed outside the contact hole to form a contact plug; selectively leaving the adhesive film within the contact hole by removing the adhesive film formed on the insulating film; and forming a metal interconnect in contact with the contact plug.

According to this manufacturing method, a titanium-containing film can be stably formed within the contact plug, and a solid-state imaging device with suppressed dark current can be manufactured suitably.

In the above-mentioned manufacturing method, the removing the tungsten film and the removing the adhesive film formed on the insulating film may be performed by etchback or polishing. Moreover, these processes may be performed by a series of steps based on etchback or by a series of steps based on polishing. In this case, an etching gas or polishing slurry may be changed appropriately in each process.

Although the structure of the present invention was explained above, any combination of the above-mentioned structures and a modification of the present invention such that its representation is changed by converting the method into the device and vice versa are effective as embodiments of the invention.

According to the present invention, since the titanium-containing film is selectively formed within the contact plug, the dark current can be reduced effectively without increasing the contact resistance.

### BRIEF DESCRIPTION OF THE DRAWINGS

The above and other objects, advantages and features of the present invention will be more apparent from the following description taken in conjunction with the accompanying drawings, in which:

FIG. 1 is a plan view showing a structure of a solid-state imaging device in an embodiment of the present invention;

FIG. 2 is a cross-sectional view showing the structure of the solid-state imaging device in the embodiment of the present invention;

FIG. 3 is a cross-sectional view showing the structure of the solid-state imaging device in the embodiment of the present invention;

FIGS. 4A to 4C are cross-sectional views showing a manufacturing process of the solid-state imaging device in the embodiment of the present invention;

FIGS. 5A to 5C are cross-sectional views showing a manufacturing process of the solid-state imaging device in the embodiment of the present invention;

FIGS. 6A to 6C are cross-sectional views showing the manufacturing process of the solid-state imaging device in the embodiment of the present invention;

FIG. 7 is a cross-sectional view showing a structure of a solid-state imaging device in an embodiment of the present invention;

FIG. 8 is a cross-sectional view showing a structure of a solid-state imaging device in an embodiment of the present invention;

FIG. 9 is a cross-sectional view showing a structure of a solid-state imaging device of an example; and

FIG. 10 is a diagram showing a measurement result of dark current of the solid-state imaging devices of an example.

### DETAILED DESCRIPTION OF THE INVENTION

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### First Embodiment

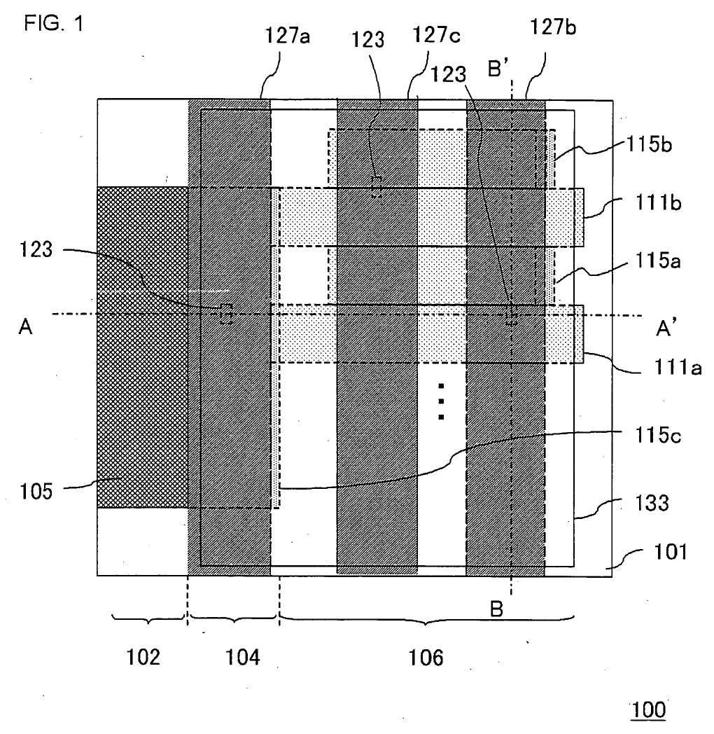

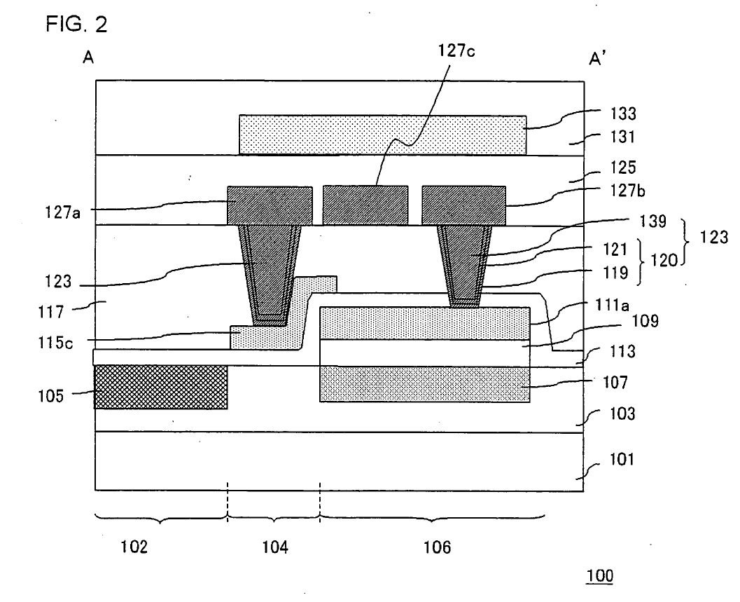

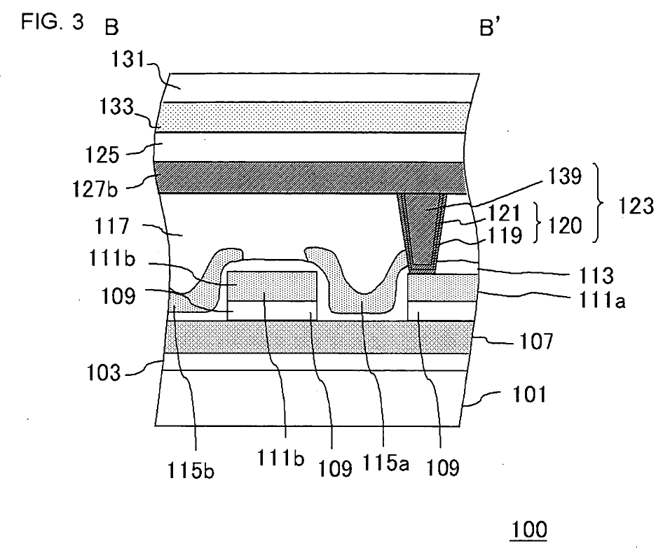

FIG. 1 is a plan view showing a structure of a solid-state imaging device according to this embodiment. A solid-state imaging device 100 shown in FIG. 1 is a one-dimensional CCD image sensor. FIG. 2 is an A-A′ cross-sectional view of the solid-state imaging device 100 in FIG. 1. FIG. 3 is a B-B′ cross-sectional view of the solid-state imaging device 100 in FIG. 1.

The solid-state imaging device 100 shown in FIGS. 1 to 3 comprises an N-type semiconductor substrate 101, electroconductive regions (a first polycrystalline silicon electrode 111a and a second polycrystalline silicon electrode 115c) provided on the N-type semiconductor substrate 101, an insulating film (a second insulating interlayer 117) formed on the electroconductive region, Al interconnects (first Al interconnects 127a, 127b) provided on the insulating film, contact plugs 123 each of which is provided in the insulating film and connects the lower surface of the Al interconnect and the electroconductive region, and an adhesive film 120 containing Ti and selectively formed within each contact plug 123.

Moreover, as shown in FIGS. 1 and 2, in the solid-state imaging device 100, a photodiode 105 and a diffusion layer 107 are provided in the vicinity of a surface of the N-type semiconductor substrate 101 (N-type silicon substrate), and a P-well 103 is formed to include these members. Moreover, in the vicinity of the surface of the semiconductor substrate, a photodiode section 102, a read-out section 104, and a transfer CCD section 106 are provided being placed side by side.

The photodiode section 102 is provided on the surface of the N-type semiconductor substrate 101 and has the photodiode 105, a plurality of the photodiodes 105 being arranged in a predetermined direction and isolated by an element separation layer.

The read-out section 104 has a function of photoelectrically converting light with the photodiode 105 and transferring accumulated charge to the transfer CCD section 106 every definite period of time. This structure has both the second polycrystalline silicon electrode 115c on the diffusion layer of a conductivity type opposite to that of the photodiode, and the first Al interconnect 127a that is provided on the second polycrystalline silicon electrode 115c and extends almost parallel to the second polycrystalline silicon electrode 115c. The first Al interconnect 127a and the second polycrystalline silicon electrode 115c are electrically connected by the contact plug 123.

In the transfer CCD section 106, as shown in FIG. 1, the first polycrystalline silicon electrode and the second polycrystalline silicon electrode each of which extend in a direction substantially perpendicular to the extension direction of the second polycrystalline silicon electrode 115c are provided alternately. FIG. 1 shows only a second polycrystalline silicon electrode 115b, a first polycrystalline silicon electrode 111b, a second polycrystalline silicon electrode 115a, and the first polycrystalline silicon electrode 111a away from the end side (upper portion in the figure) of the N-type semiconductor substrate 101. However, as shown by a symbol “ . . . ” in the figure, the transfer CCD section 106 may have a structure where a predetermined number of pairs of the first polycrystalline silicon electrodes and the second polycrystalline silicon electrodes are provided away from the first polycrystalline silicon electrode 111a (lower portion in the figure).

Moreover, in the transfer CCD section 106, as shown in FIGS. 2 and 3, the diffusion layer 107 functioning as a charge transfer region is provided on the surface of the N-type semiconductor substrate 101, and adjacent to this, the photodiode 105 is provided. The charge accumulated in the photodiode 105 is transferred to the first polycrystalline silicon electrode 111a through the second polycrystalline silicon electrode 115c.

A first gate oxide film 109 and the first polycrystalline silicon electrode 111a are formed on the diffusion layer 107 in this order. The first polycrystalline silicon electrode 111a functions as a charge transfer electrode.

On the first polycrystalline silicon electrode 111a, the first polycrystalline silicon electrode 111b, the second polycrystalline silicon electrode 115a, and the second polycrystalline silicon electrode 115b, there is provided the first Al interconnect 127b that is in the same layer as the first Al interconnect 127b and is almost in parallel thereto. A second Al interconnect 133 is provided on these first Al interconnects 127a, 127b. A first Al interconnect 127c is provided between the first Al interconnects 127a, 127b.

The second polycrystalline silicon electrode 115a and the first polycrystalline silicon electrode 111a are electrically connected with the first Al interconnect 127b through the contact plug 123 functioning as an electroconductive common contact plug. The second polycrystalline silicon electrode 115b and the first polycrystalline silicon electrode 111b are electrically connected with the first Al interconnect 127c through the contact plug 123. The bottom surfaces of the first Al interconnect 127a, the first Al interconnect 127b, the first Al interconnect 127c, and the second Al interconnect 133 are in contact with the insulating film except for a region in contact with the contact plug 123.

The second Al interconnect 133 is a planar interconnect that functions as a light-shielding film and is provided in an area ranging from the read-out section 104 to the transfer CCD section 106, being in a level higher than both the first Al interconnect 127a and the first Al interconnect 127b of the N-type semiconductor substrate 101.

The contact plug 123 is constructed with a W (tungsten) film 139 embedded in the contact hole and the adhesive film 120 covering its surroundings. The adhesive film 120 is constructed with an electroconductive titanium-containing film, and is formed in such a form as to cover inner walls (the whole bottom and side surfaces) of the contact hole. Here, the adhesive film 120 has a composition such that a Ti film 119 and a TiN film 121 are successively layered in this order from the N-type semiconductor substrate 101 side.

The adhesive film 120 is selectively formed only in the side and bottom surface of the contact plug 123, in a region between the first Al interconnect 127a and the second polycrystalline silicon electrode 115c beneath and in a region between the first Al interconnect 127b and the first polycrystalline electrode 111a beneath. The end of the adhesive film 120 is in the contact plug 123. In a region other than the forming region of the contact plug 123, the adhesive film 120 containing titanium is not formed under the first Al interconnect 127a and the first Al interconnect 127b, and these first Al interconnects 127a, 127b are in direct contact with the second insulating interlayer 117.

Incidentally, although not shown in FIGS. 1 to 3, a titanium-containing film, such as a TiN film, that functions, for example, as an antireflection coating may be appropriately formed on the first Al interconnect 127a or first Al interconnect 127b, for example, on the top surface of one of these first Al interconnects.

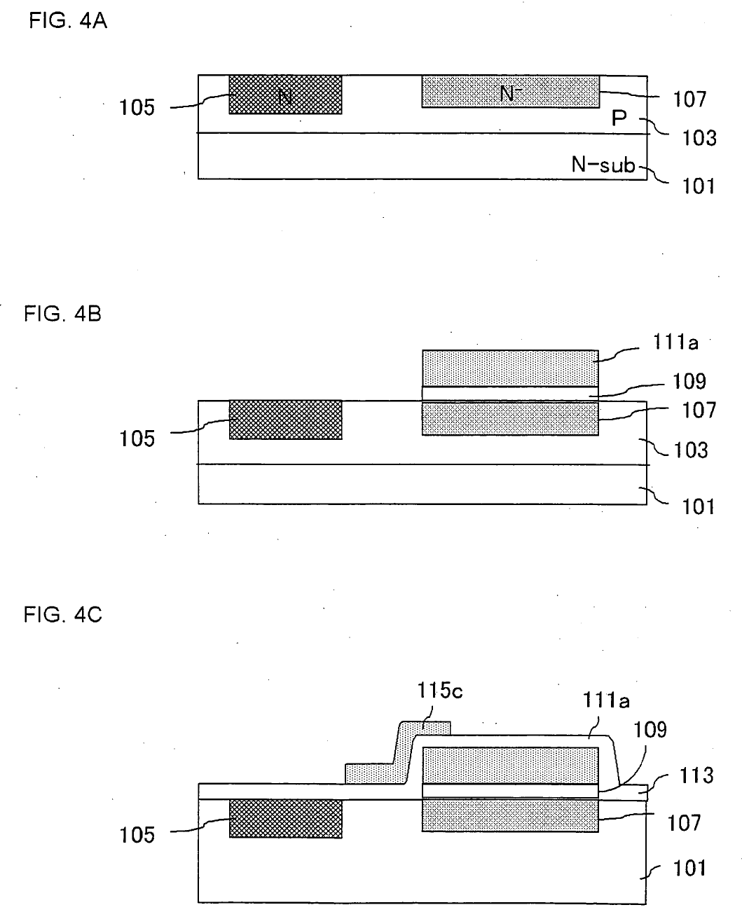

Next, with reference to FIGS. 4A-4C, FIGS. 5A-5C, and FIGS. 6A-6C, the method of manufacturing the solid-state imaging device 100 shown in FIGS. 1 to 3 will be described. Like FIG. 2, FIGS. 4A-4C, FIGS. 5A-5C, and FIGS. 6A-6C are A-A′ cross-sectional views of the solid-state imaging device 100 of FIG. 1.

As shown in FIG. 4A, first, an impurity, such as boron, is ion-implanted to form a P-well 103. Next, an impurity, such as phosphorus, is ion-implanted into a predetermined region of the N-type semiconductor substrate 101 to construct the photodiode 105. Subsequently, an impurity, such as phosphorus (P), is ion-implanted into the predetermined region of the N-type semiconductor substrate 101 to form the diffusion layer 107 functioning as a charge transfer channel.

Following this, the first gate oxide film 109 is formed in a region in which the diffusion layer 107 and the photodiode 105 were formed. Preferably, the first gate oxide film 109 is formed by heat treatment. By this treatment, a junction plane between the first gate oxide film 109 and the N-type semiconductor substrate 101 can be stabilized. Then, the first polycrystalline silicon electrode 111a and the first polycrystalline silicon electrode 111b that function as gate electrodes are selectively formed on the first gate oxide film 109 by the lithography and etching technology (FIG. 4B).

Next, a second gate oxide film 113 is formed on the first polycrystalline silicon electrode 111a by a thermal oxidation method. Subsequently, the second polycrystalline silicon electrodes 115a, 115b, and 115c are formed in predetermined regions of the read-out section 104 and of the transfer CCD section 106 by the lithography and etching technology (FIG. 4C).

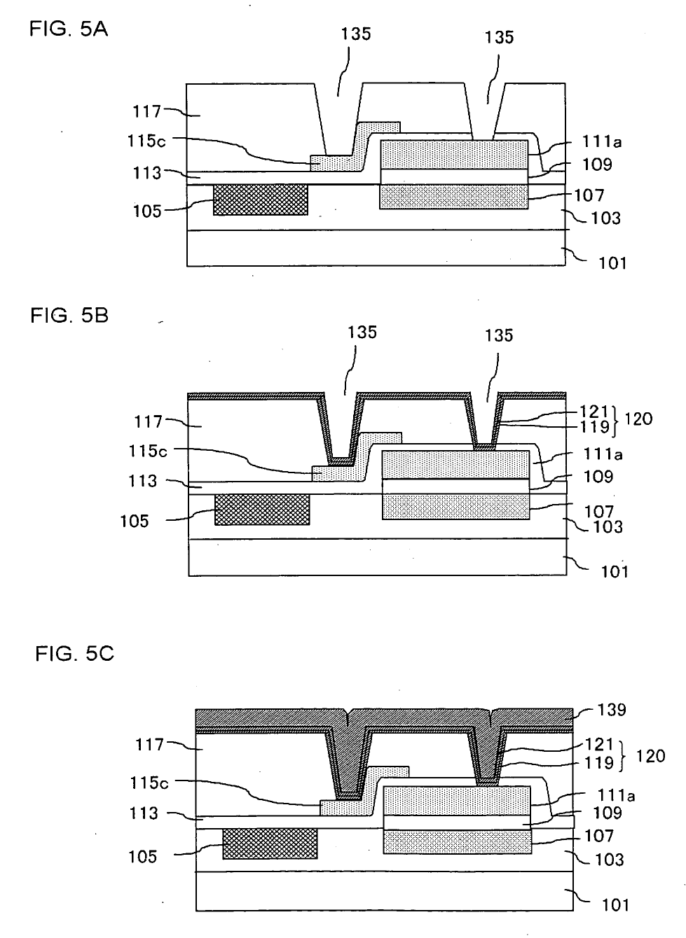

Following this, a BPSG (Boron-Phospho-Silicate-Glass) film as the second insulating interlayer 117 is formed by the CVD method on the N-type semiconductor substrate 101 on which the second polycrystalline silicon electrode was provided. Then, the second insulating interlayer 117 is selectively removed by the lithography and etching technology, and contact holes 135 are bored at predetermined positions on the first polycrystalline silicon electrode and the second polycrystalline silicon electrode (FIG. 5A).

Next, the Ti film 119 and the TiN film 121 are formed successively in this order by sputtering on the whole surface of the second insulating interlayer 117 (FIG. 5B). Thicknesses of the Ti film 119 and the TiN film 121 are specified, for example, as 100 nm and 50 nm, respectively. The TiN film 121 may be formed by a reactive sputter method.

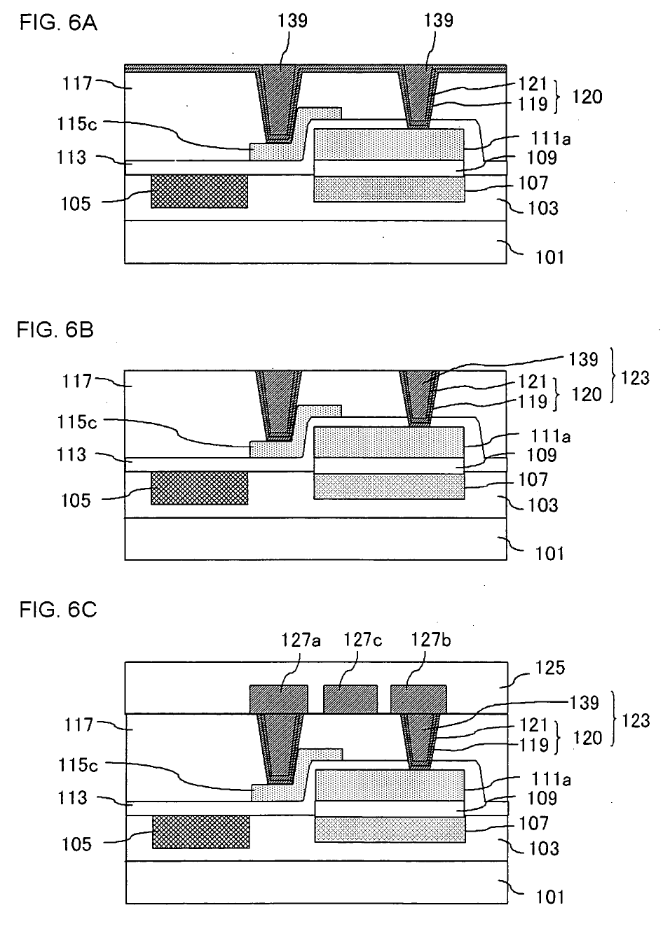

Subsequently, the W film 139 is formed on the whole surface of the N-type semiconductor substrate 101 to fill the contact holes 135 by the CVD method (FIG. 5C). Then, the W film 139 that is formed in a region other than the contact holes 135 is removed by performing etchback on the W film 139 using SF6 gas or the like (FIG. 6A).

After this, the TiN film 121 and the Ti film 119 formed on the second insulating interlayer 117 are removed using a chlorine-containing gas or a chloride-containing gas, concretely chlorine gasses of Cl₂, BCl₃, and the like, to selectively leave the Ti film 119 and the TiN film 121 within the contact hole 135, whereby the surface of the second insulating interlayer 117 is exposed (FIG. 6B).

Next, an Al film in contact with the second insulating interlayer 117 is formed by sputtering and selectively left only in a predetermined region by the lithography and etching technology, whereby the first Al interconnect 127a and the first Al interconnect 127b (also called the first Al interconnect collectively) in contact with the contact plug 123 are formed. Then, a first oxide film 125 is formed as an insulating interlayer that embeds these first Al interconnects. Similarly, the second Al interconnect 133 and a second oxide film 131 are formed subsequently on the first oxide film 125. These oxide films are deposited by a plasma CVD method and the like (FIG. 6C).

Subsequently, a sintering treatment is performed using hydrogen gas that is being introduced on the N-type semiconductor substrate 101. The conditions of the sintering treatment are specified, for example, as a temperature of about 300 to 450 degree centigrade and about 20 to 60 minutes. By this procedure, the solid-state imaging device 100 having the structure shown in FIGS. 1 to 3 is obtained.

Next, the effect of the solid-state imaging device 100 shown in FIGS. 1 to 3 will be described. The solid-state imaging device 100 has the following structure: a multilayer film consisting of the Ti film 119 and the TiN film 121, which are titanium-containing films, is used in the contact plug 123 as the adhesive film 120 that establishes electric contact between (a) the first Al interconnect and (b) the first polycrystalline silicon electrode, the second polycrystalline electrode, the source and drain regions of an unillustrated transistor or electroconductive regions that constitute a peripheral circuit such as other interconnects and plugs, and; the plugs are formed with the W film 139; and the titanium-containing film does not exist under any portions of the first Al interconnects other than the above-mentioned portions. That is, the titanium-containing film is selectively formed in the contact plug 123, while the titanium-containing film is not formed under the first Al interconnects in a region outside the contact plug 123. Therefore, by performing the sintering treatment with hydrogen gas, it is possible to introduce hydrogen into the N-type semiconductor substrate 101 efficiently, and consequently to extinguish interface levels of the photodiode 105 and the diffusion layer 107 provided in the N-type semiconductor substrate 101. By this mechanism, reduction in dark current of the photodiode 105 and the diffusion layer 107 is achieved.

Although the titanium-containing film was selectively formed only in the contact plug forming part on the lower surface side of the Al interconnect, a titanium-containing film, such as a TiN film, functioning as antireflection coating, may be formed on the top surface of the Al interconnect. In order to make the titanium-containing film deliver a sintering effect sufficiently and reduce the dark current by suppressing adsorption of hydrogen, it is important to adopt the structure described above in a region under the metal interconnect. Therefore, a titanium-containing film may be formed on the top surface side of the interconnect.

In the technology described in the above-mentioned Japanese Laid-open patent application No. 2003-229556 and Japanese Laid-open patent application No. 1996-37236, tungsten silicide and the like is used as a material of a covering layer that covers the bottom and side of the plug. In this case, the contact resistance increases and interconnect delay occurs. On the other hand, the solid-state imaging device 100 of this embodiment can reduce the dark current while suppressing interconnect delay by decreasing contact resistance sufficiently, because it uses the titanium-containing film of low resistance as the adhesive film 120. This effect is more notably delivered in the case where the adhesive film 120 is formed to cover the whole surroundings of the contact plug 123. Moreover, since titanium is a material used frequently in the standard logic process and usable in the existing equipment, titanium can be used without introducing a new material and new equipment.

Moreover, since in the solid-state imaging device 100, the contact plug 123 has a plug made up of the W film 139, it becomes possible to fabricate a finer structure compared to a method of establishing direct connection with an Al film that constitutes the first Al interconnect.

In addition, the solid-state imaging device 100 may have a structure where also in the region between the second Al interconnect 133 and an electroconductive region provided under the second Al interconnect 133, the titanium-containing film is selectively formed only within the contact plug connecting them, so that the second Al interconnect 133 is in contact with the first oxide film 125 in a region of the bottom surface of the second Al interconnect other than the region where that bottom surface is in contact with the contact plug. With this structure, the effect described above is delivered still more notably.

Moreover, in the solid-state imaging device 100, interconnects of the peripheral circuit formed by the same process as is taken for one of the first Al interconnect 127a, the first Al interconnect 127b, and the second Al interconnect 133 may be provided on the same layer as any one of these Al interconnects. By modifying this structure to a structure where a titanium-containing film is selectively formed within the contact plug 123 that connects the interconnect of the peripheral circuit and an electroconductive region provided nearer to the N-type semiconductor substrate 101 than thed interconnect, the dark current can be controlled more positively.

Note that in the manufacturing process of the solid-state imaging device 100, etchback as the process of removing the W film 139 (FIG. 6A) and the process of removing the adhesive film 120 (FIG. 6B) can be replaced with polishing by CMP (Chemical Mechanical Polishing) and the like.

The embodiments below will be described focusing several points that are different from the first embodiment.

### Second Embodiment

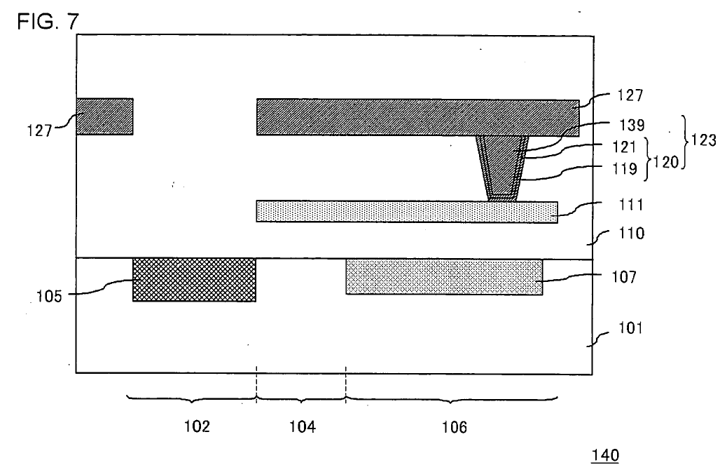

FIG. 7 is a cross-sectional view showing a structure of a solid-state imaging device according to this embodiment. FIG. 7 corresponds to a figure viewed from the same direction as that in FIG. 2. A solid-state imaging device 140 shown in FIG. 7 is a two-dimensional CCD image sensor that employs the basic structure shown in FIGS. 1 to 3.

Also in the solid-state imaging device 140 shown in FIG. 7, the adhesive film 120 is selectively formed within the contact plug 123 that connects the first polycrystalline silicon electrode 111 and the first Al interconnect 127 in a region between the first Al interconnect 127 and the first polycrystalline silicon electrode 111, and the adhesive film 120 is not formed in any region other than the region where the bottom surface of the first Al interconnect 127 is in contact with the contact plug 123. Therefore, the same effect as that of the solid-state imaging device 100 shown in FIGS. 1 to 3 can be achieved.

### Third Embodiment

In the above embodiments, the cases where the solid-state imaging device was the CCD image sensor were illustrated. However, the structure of the present invention is also applicable to the CMOS (complementary metal oxide semiconductor) image sensor.

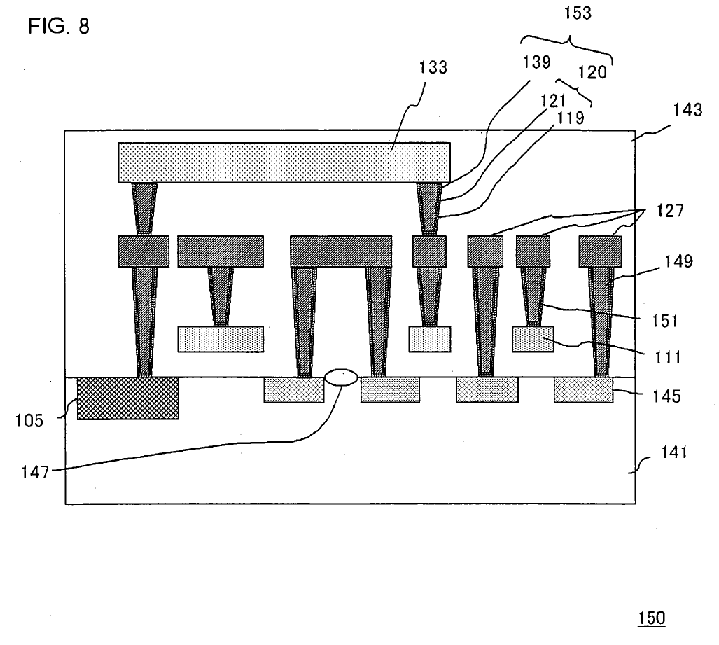

FIG. 8 is a cross-sectional view showing a structure of a CMOS image sensor of this embodiment. FIG. 8 corresponds to a view of the CMOS image sensor viewed from the same direction as that of FIG. 2. A solid-state imaging device 150 shown in FIG. 8 comprises a P-type semiconductor substrate 141, the photodiode 105 formed on the surface of the P-type semiconductor substrate 141, and an N⁺ well 145 that is formed on the surface of the P-type semiconductor 141 being placed side by side with the photodiode 105, and a LOCOS (local oxidation of silicon) isolating adjacent the N⁺ wells 145.

Moreover, the solid-state imaging device 150 has a gate insulating film (not shown in the drawings) formed on the N⁺ well 145 and the first polycrystalline silicon electrode 111 that is formed on the gate insulating film and functions as a gate electrode. Furthermore, the first Al interconnect 127 and the second Al interconnect 133 were formed on the first polycrystalline silicon electrode 111 in this order, and these members are embedded by an insulating film 143. For the insulating film 143, a composition made up of two or more layers of insulating films may be adopted.

In the solid-state imaging device 150, the structure of the contact plug 123 (FIG. 2) described in the above embodiments was applied to: a contact plug 149 that connects the N⁺ well 145 and the first Al interconnect 127, a contact plug 151 that connects the first polycrystalline silicon electrode 111 and the first Al interconnect 127, and a contact plug 153 that connects the second Al interconnect 133 and the first Al interconnect 127. Moreover, the adhesive film 120 is selectively formed within the contact plug 123, so that the adhesive film 120 does not exist in any regions of the bottom surfaces of the first Al interconnect 127 and the second Al interconnect 133 other than the regions where the bottom surfaces are in contact with the contact plug 123. With this structure, also in the CMOS image sensor, the same effect as that of the above embodiments can be achieved.

In the foregoing, the embodiments of the present invention were described with reference to the drawings, but it should be noted that these are only illustrations of the present invention and various structures other than what were described above may be adopted.

For example, although the above embodiments have the structure where the contact plug 123 has the plug made up of the W film 139, other film of metal with high melting temperature, a Cu film, and the like maybe used in the place of the W film 139. Moreover, the adhesive film 120 only needs to be of a composition containing Ti, not limited to a multilayer film consisting of the Ti film 119 and the TiN film 121. Therefore, it may have any structure consisting of a Ti film, a Ti alloy film, or other electroconductive films containing Ti. Also, the adhesive film 120 may be any combination of these films, and may be either a single layer or a multilayer film.

Moreover, in the above embodiments, the cases where the metal interconnect was the Al interconnect were explained by way of example. However, a material of the metal interconnect only needs to be a metal that contains aluminum mainly. “Mainly containing aluminum” means that a main constituent of the metal interconnect is aluminum (Al), that is, the metal interconnect may contain an alloy of Al and other metal and the like as well as containing only aluminum. In the case where the metal interconnect contains a metal other than Al, the ratio of Al to the whole constituents of the metal interconnect can be, for example, 90 at % or more. As such a material, for example, an alloy metal of Al and Cu is given. cl Example

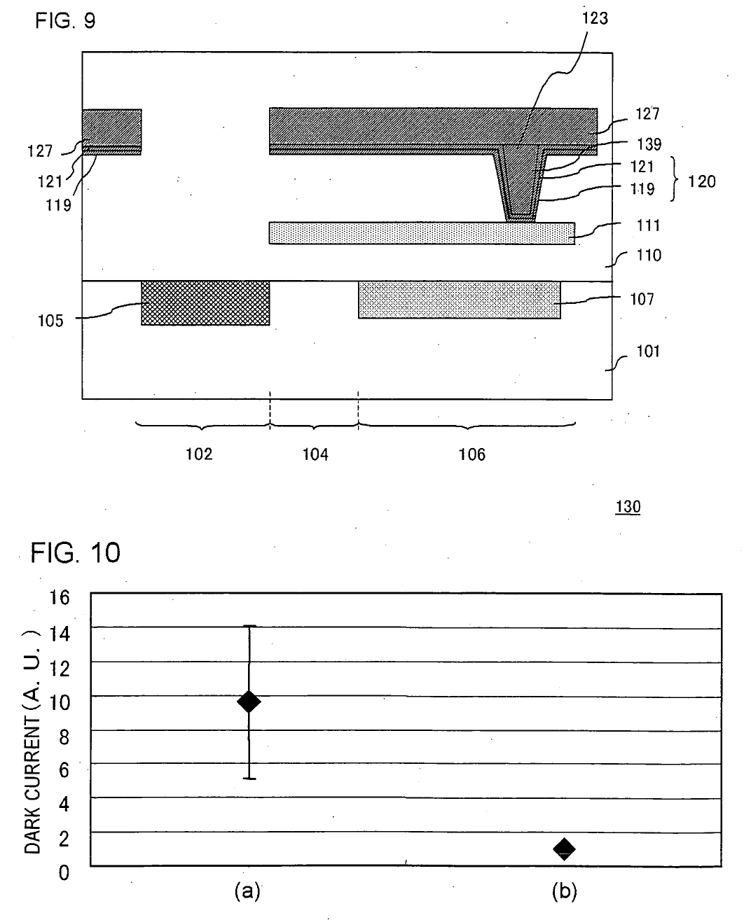

In this example, the solid-state imaging devices shown in FIGS. 7 and 9 were produced, and the dark current was evaluated. The solid-state imaging device 140 illustrated in FIG. 7 has the structure where the titanium-containing film is selectively formed only within the contact plug 123. A solid-state imaging device 130 shown in FIG. 9 has the structure where the adhesive film 120 is formed being in contact with the whole lower surface of the first Al wring 127 in the solid-state imaging device 140 illustrated in FIG. 7.

FIG. 10 is a diagram showing measurement results of the dark current in these devices. In the figure, (a) designates an evaluation result of the solid-state imaging device 130 shown in FIG. 9, and (b) in the figure designates an evaluation result of the solid-state imaging device 140 shown in FIG. 7. As can be seen from the results shown in FIG. 10, it has become clear that, by selectively providing the titanium-containing film only within the contact plug 123, the dark current can be reduced effectively.

It is apparent that the present invention is not limited to the above embodiment, that may be modified and changed without departing from the scope and spirit of the invention.

What is claimed is:

1. A solid-state imaging device containing a photosensor, the solid-state imaging device comprising:
a substrate;
an electroconductive region formed on said substrate;
an insulating film formed on said electroconductive region;
a metal interconnect provided on said insulating film;
a contact plug that is provided in said insulating film and connects a lower surface of said metal interconnect and said electroconductive region; and
a titanium-containing film selectively formed within said contact plug.

2. The solid-state imaging device as set forth in claim 1,
wherein said titanium-containing film is formed only in a lower part and on a side face of said contact plug.

3. The solid-state imaging device as set forth in claim 1,
wherein said insulating film and said metal interconnect are in direct contact with each other.

4. The solid-state imaging device as set forth in claim 1, further comprising:
a charge transfer region arranged side by side with said photosensor on said substrate,
a gate insulating film formed on said charge transfer region, and
a charge transfer electrode provided on said gate insulating film.

5. The solid-state imaging device as set forth in claim 4,
wherein said substrate is a semiconductor substrate, and said electroconductive region is one of a diffusion layer provided in the vicinity of a surface of said semiconductor substrate, said charge transfer electrode, and a interconnect formed closer to said semiconductor substrate than said metal interconnect.

6. The solid-state imaging device as set forth in claim 1,
wherein said substrate is a semiconductor substrate, the solid-state imaging device further comprising:
a complementary field effect transistor that includes said diffusion layer provided on a surface of said semiconductor substrate, a gate insulating film formed on said diffusion layer, and a gate electrode provided on said gate insulating film.

7. The solid-state imaging device as set forth in claim 6,
wherein said substrate is a semiconductor substrate and said electroconductive region is one of a diffusion layer provided in the vicinity of the surface of said semiconductor substrate, said gate electrode, and a interconnect formed closer to said semiconductor substrate than said metal interconnect.

8. The solid-state imaging device as set forth in claim 1,
wherein said metal interconnect is made up of metals that mainly contain aluminum.

9. A method of manufacturing a solid-state imaging device, comprising:
providing an insulating film on a semiconductor substrate on which a photosensor is provided;
selectively removing said insulating film to form a contact hole;
forming an adhesive film containing a titanium-containing film on said insulating film in which said contact hole was formed;
forming a tungsten film so that it fills said contact hole;
removing said tungsten film formed outside said contact hole to form a contact plug;
selectively leaving said adhesive film within said contact hole by removing said adhesive film formed on said insulating film; and
forming a metal interconnect in contact with said contact plug.

10. The method of manufacturing a solid-state imaging device as set forth in claim 9,
wherein said forming the contact plug includes removing said tungsten film formed outside said contact hole by etchback, and
said selectively leaving said adhesive film within said contact hole includes removing said adhesive film formed on said insulating film by performing etchback using a chlorine-containing gas or a chloride-containing gas.

11. The method of manufacturing a solid-state imaging device as set forth in claim 9,
wherein said forming said contact plug includes removing said tungsten film formed outside said contact holes by polishing, and said selectively leaving said adhesive film within said contact hole includes removing said adhesive film formed on said insulating film by polishing.

12. The method of manufacturing a solid-state imaging device as set forth in claim 9, further comprising:
after said forming said metal interconnect, performing sintering while introducing hydrogen on said semiconductor substrate.
